(19) United States
(12) Patent Application Publication
(10) Pub. No.: US 2025/0149436 A1
(43) Pub. Date: May 8, 2025

(54) INTERCONNECT STRUCTURE WITH LOW RC DELAY AND METHOD FOR MANUFACTURING THE SAME

(71) Applicant: TAIWAN SEMICONDUCTOR MANUFACTURING COMPANY, LTD., Hsinchu (TW)

(72) Inventors: Gary LIU, Hsinchu (TW); Ting-Ya LO, Hsinchu (TW); Shao-Kuan LEE, Hsinchu (TW); Zi-Yi YANG, Hsinchu (TW); Chi-Lin TENG, Hsinchu (TW); Kuang-Wei YANG, Hsinchu (TW); Hsin-Yen HUANG, Hsinchu (TW); Hsiao-Kang CHANG, Hsinchu (TW); Ming-Han LEE, Hsinchu (TW); Shau-Lin SHUE, Hsinchu (TW)

(73) Assignee: TAIWAN SEMICONDUCTOR MANUFACTURING COMPANY, LTD., Hsinchu (TW)

(21) Appl. No.: 18/502,640

(22) Filed: Nov. 6, 2023

(51) Int. Cl. H01L 23/522; H01L 21/02; H01L 21/3105; H01L 21/768; H01L 23/528

(52) U.S. Cl. CPC H01L 23/5226; H01L 21/02362; H01L 21/31058; H01L 21/76829; H01L 23/5283

(57) ABSTRACT

A method for manufacturing an interconnect structure includes: forming sacrificial portions and electrically conductive portions on a base structure such that the sacrificial portions are disposed to alternate with the electrically conductive portions in a first direction, and such that each of the sacrificial portions and the electrically conductive portions is elongated in a second direction transverse to the first direction; forming blocking portions respectively on the sacrificial portions; forming a sacrificial layer to cover the electrically conductive portions and the blocking portions; forming an electrically conductive via which extends through the sacrificial layer so as to permit the electrically conductive via to be electrically connected to one of the electrically conductive portions; after forming the electrically conductive via, performing a removal process to remove the sacrificial layer, the blocking portions and the sacrificial portions so as to form a cavity; and forming a dielectric portion to fill the cavity.

### BACKGROUND

With the size miniaturization of a semiconductor device, interconnect features (e.g., metal lines, vias, contacts, etc.) that interconnect the semiconductor device to an external circuit have reduced dimensions, which leads to an increased electrical resistance, and an inter-layer dielectric that separates two adjacent interconnects also has a reduced dimension, which leads to an increased dielectric capacitance between the two adjacent interconnect features. Therefore, in the development of next generation interconnect structure, how to reduce signal delay and to increase the speed of an integrated circuit are key challenges to be overcome so as to obtain interconnect features with low electrical resistivity and the inter-metal dielectric with low dielectric capacitance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure including an interconnect structure in accordance with some embodiments.

FIGS. 2 to 17 illustrate schematic views of intermediate stages of the method depicted in FIG. 1 in accordance with some embodiments.

FIG. 18 is a schematic sectional view illustrating a semiconductor structure in accordance with some other embodiments.

FIG. 19 is a schematic plane view of a semiconductor structure in accordance with some yet other embodiments.

FIG. 20 is schematic sectional view taken along line B-B of FIG. 19 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In general, a semiconductor structure has a front-end-of-line (FEOL) portion which includes multiple functional devices, a back-end-of-line (BEOL) portion which includes multiple metal lines and metal vias, and a middle-of-line (MOL) portion configured to permit the multiple functional devices to be connected to the BEOL portion. In the BEOL portion, an inter-metal dielectric (IMD) is disposed to separate two adjacent metal lines (or metal vias), and the IMD is likely to be damaged during formation of the metal lines (or the metal vias) in the IMD, and the damaged IMD thus has an increased dielectric constant (k-value). As such, many approaches are being developed for preventing or eliminating the damage of the IMD.

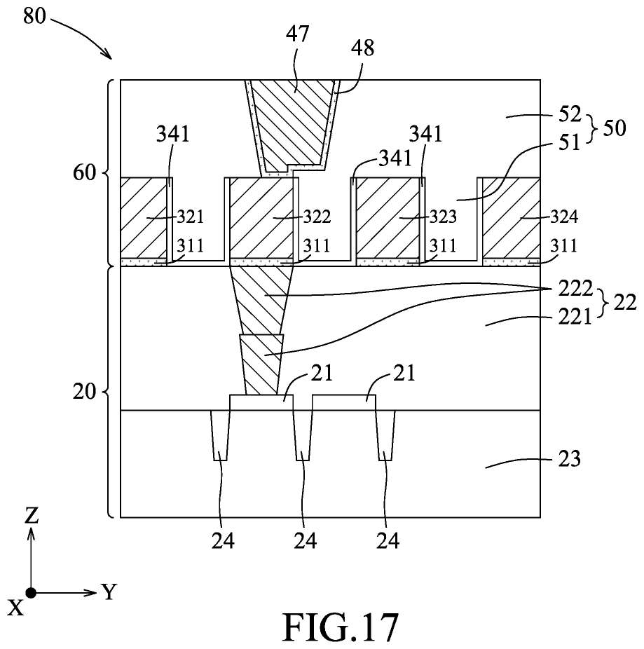

The BEOL portion includes multiple metal layers and multiple via layers disposed to alternate with the metal layers. The first metal layer (MO) is the metal layer that is the most proximate to the FEOL portion, and the first via layer (VO) is the via layer that is formed on the first metal layer (MO) opposite to the FEOL portion. Metal lines in the first metal layer (MO) and metal vias in the first via layer (VO) have a minimum pattern size or pitch in the BEOL portion. In the case that the metal lines in the first metal layer (MO) are formed in a lower IMD using a single damascene technique, the lower IMD may be damaged by etching step(s) used in the single damascene technique. In order to reduce damage to the lower IMD during formation of the metal lines in the first metal layer (MO), the lower IMD may be formed after formation of the metal lines by depositing a dielectric material over the metal lines using a deposition process (e.g., spin-coating), followed by a planarization process to expose the metal lines. In the case that the metal vias in the first via layer (VO) is formed in an upper IMD using a single damascene technique or a dual damascene technique, formation of an etch stop layer between the upper IMD and the lower IMD is necessary. However, the lower IMD is still at risk of being damaged by a pre-clean process before forming the etch stop layer or by a plasma-enhanced deposition process for forming the etch stop layer. Therefore, the present disclosure is directed to formation of an interconnect structure (for example, an interconnect structure 60 shown in FIG. 17), in which a dielectric portion (e.g., the element 50 shown in FIG. 17) is formed after formation of metal portions. Hence, the damage to the dielectric portion in the interconnect structure can be significantly reduced. In some embodiments, the metal portions include the metal lines in the first metal layer (MO) and the metal vias in the first via layer (VO). In some other embodiments, the metal portions include (i) metal lines of any one of the metal layers (Mx) that is at a higher level than the first metal layer (MO) in the BEOL portion and (ii) metal vias of one adjacent via layer (Vx) that is formed on the metal layer (Mx) opposite to the FEOL portion.

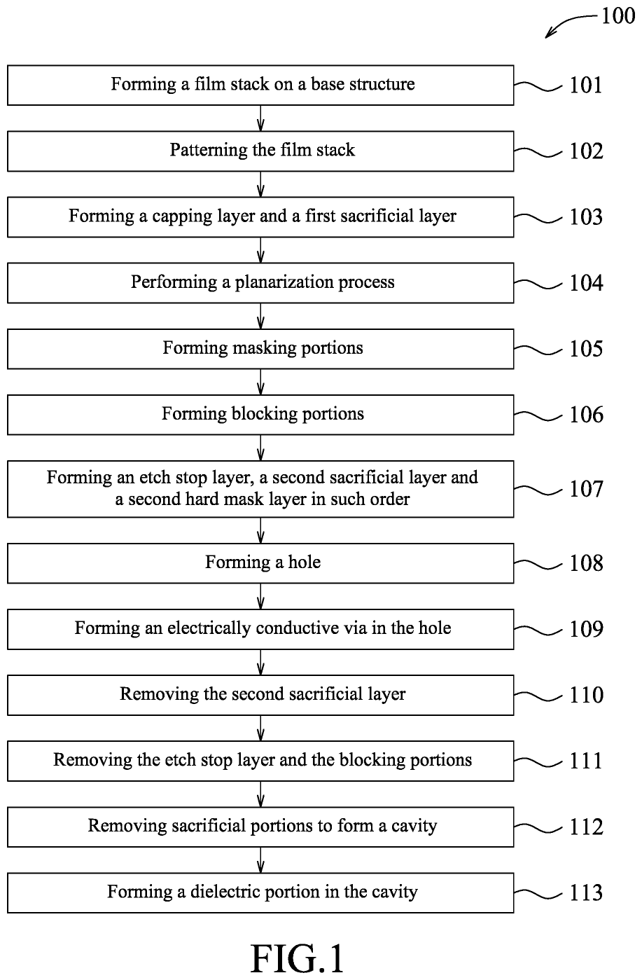

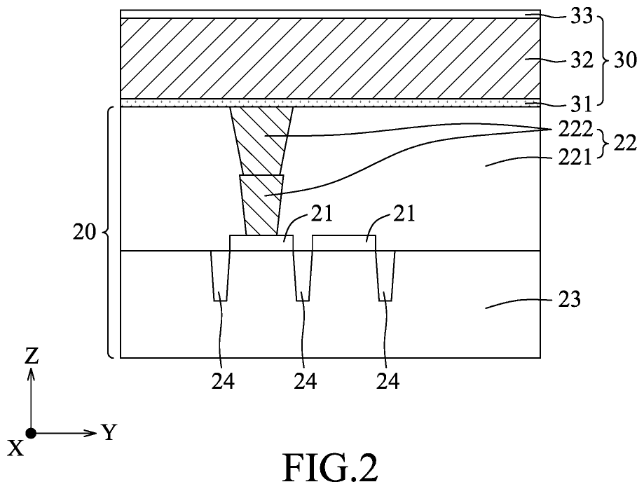

FIG. 1 is a flow diagram illustrating a method 100 for manufacturing a semiconductor structure (for example, a semiconductor structure 80 shown in FIG. 17) including an interconnect structure (e.g., the interconnect structure 60 in FIG. 17) in accordance with some embodiments. FIGS. 2 to 17 illustrate schematic views of intermediate stages of the method 100 in accordance with some embodiments. Some structures are omitted in FIGS. 2 to 17 for the sake of brevity.

Referring to FIG. 1 and the examples illustrated in FIG. 2, the method 100 begins at step 101, where a film stack 30 is formed on a base structure 20. The film stack 30 includes a glue layer 31, an electrically conductive layer 32 and a hard mask layer 33 stacked on one another in such order.

In some embodiments, the base structure 20 includes multiple functional devices 21 (two of which are shown in FIG. 2) respectively formed on active regions of a substrate 23. The functional devices 21 may include active devices (such as transistors, or the like), passive devices (such as capacitors, resistors, or the like), decoders, amplifiers, or combinations thereof. The transistors may include fin-type field-effect transistors (FinFETs), gate-all-around (GAA) transistors, or a combination thereof. The transistors may be arranged in a complementary field-effect transistors (CFET) structure, in which two GAA transistors are stacked on one another in a Z direction. The transistors may be arranged in a fork-sheet structure, in which two GAA transistors are spaced part from each other in a Y direction through a wall portion. The Y direction is transverse to the Z direction. Other configurations suitable for the functional devices 21 are within the contemplated scope of the present disclosure.

In some embodiments, the substrate 23 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some other embodiments, the substrate 23 may be a bulk silicon substrate, a silicon-on-insulator (SOI) substrate, or a germanium-on-insulator (GOI) substrate. In some embodiments, two adjacent ones of the active regions are separated from each other by an isolation portion 24 such as a shallow trench isolation (STI) or a deep trench isolation (DTI).

In some embodiments, the base structure 20 further includes an interconnect layer 22 for being disposed between the functional devices 21 and the interconnect structure 60 (see FIG. 17) which is to be formed subsequently. The interconnect layer 22 includes a dielectric layer 221 and multiple middle-of-line contacts 222 formed in the dielectric layer 221 so as to permit each of the functional devices 21 to be electrically connected to and controlled by an external circuit.

In some embodiments, the dielectric layer 221 may include a low-k dielectric material such as silicon oxide, silicon nitride, silicon oxynitride, silicon oxycarbide, silicon carbon nitride, silicon oxycarbon nitride, phosphosilicate glass (PSG), borosilicate glass (BSG), borophosphosilicate glass (BPSG), undoped silicate glass (USG), fluorinated silicate glass (FSG), silicon oxycarbide, spin-on-glass (SOG), or combinations thereof. In some embodiments, the middle-of-line contacts 222 may include a low resistance electrically conductive material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), golden (Au), silver (Ag), aluminum (Al), osmium (Os), alloys thereof, or combinations thereof.

The glue layer 31 is formed on the interconnect layer 22 using a suitable deposition process such as physical vapor deposition (PVD), thermal chemical vapor deposition (CVD), or thermal atomic layer deposition (ALD). The glue layer 31 is provided for improving adhesion of the electrically conductive layer 32 to the interconnect layer 22. In some embodiments, the glue layer 31 may include tantalum (Ta), titanium (Ti), tantalum nitride, titanium nitride, or combinations thereof. In some embodiments, the glue layer 31 has a thickness ranging from about 2 Å to about 100 Å.

The electrically conductive layer 32 is formed on the glue layer 31 using a suitable deposition process such as physical vapor deposition (PVD), thermal chemical vapor deposition (CVD), or thermal atomic layer deposition (ALD). In some embodiments, possible electrically conductive materials suitable for the electrically conductive layer 32 are similar to those for the middle-of-line contacts 222, and thus the details thereof are omitted for the sake of brevity. In some embodiments, the electrically conductive layer 32 may have a thickness ranging from about 50 Å to about 500 Å.

The hard mask layer 33 is formed on the electrically conductive layer 32 using a suitable deposition process, such as physical vapor deposition (PVD), thermal chemical vapor deposition (CVD), plasma-enhanced chemical vapor deposition (PECVD), thermal atomic layer deposition (ALD), or plasma-enhanced atomic layer deposition (PEALD). In some embodiments, the hard mask layer 33 may include an oxide, a nitride, a carbide, an oxynitride, an oxycarbide, a carbonitride, an oxycarbonitride, or combinations thereof. For example, the hard mask layer 33 may be made of silicon oxide, aluminum oxide, hafnium oxide, zirconium oxide, silicon nitride, aluminum nitride, titanium nitride, silicon carbide, silicon oxycarbide, silicon oxynitride, silicon carbonitride, silicon oxycarbonitride, or combinations thereof.

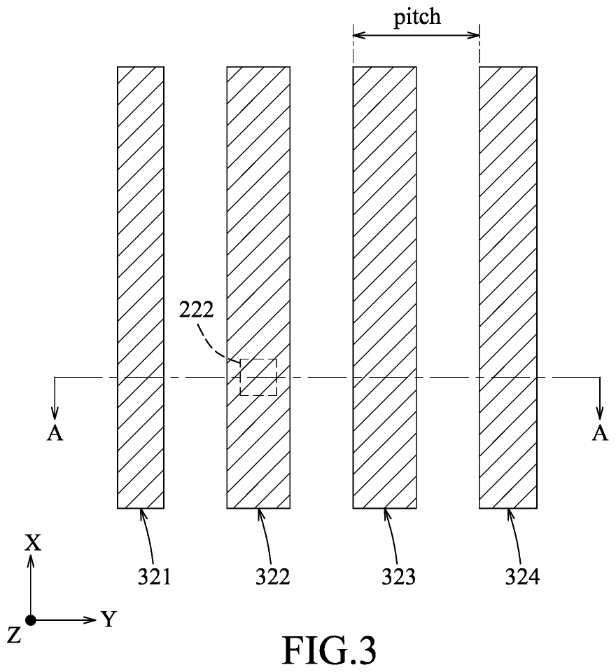

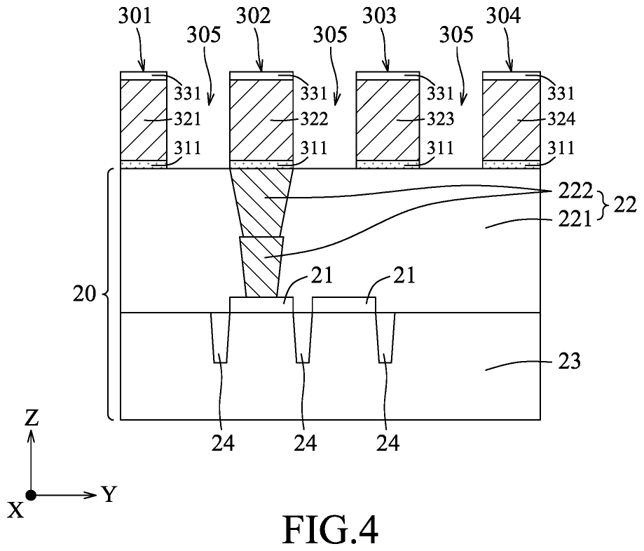

Referring to FIG. 1 and the examples illustrated in FIGS. 3 and 4, the method 100 proceeds to step 102, where the film stack 30 is patterned into multiple stacking portions 301, 302, 303, 304 (four of which are shown in FIG. 4), and multiple recesses 305 are each formed between two adjacent ones of the stack portions 301, 302, 303, 304. FIG. 3 is a schematic plane view of the structure obtained after step 102 in accordance with some embodiments, in which electrically conductive portions 321, 322, 323, 324 and one of the middle-of-line contacts 222 are shown, and other elements are omitted. FIG. 4 is a schematic sectional view subsequent to FIG. 2, and is also a schematic sectional view taken along line A-A of FIG. 3, but further illustrating the other elements omitted in FIG. 3.

As shown in FIG. 4, the hard mask layer 33 (see FIG. 2) is patterned into four hard mask portions 331, the electrically conductive layer 32 (see FIG. 2) is patterned into four electrically conductive portions 321, 322, 323, 324, and the glue layer 31 (see FIG. 2) is patterned into four glue portions 311. Each of the stacking portions 301, 302, 303, 304 includes one of the glue portions 311, a corresponding one of the electrically conductive portions 321, 322, 323, 324, and a corresponding one of the hard mask portions 331. In some embodiments, the film stack 30 is patterned by a suitable patterning process including lithography and etching processes.

In some embodiments, as shown in FIG. 3, the electrically conductive portions 321, 322, 323, 324 are each elongated in an X direction transverse to the Y and Z directions, and spaced apart from each other in the Y direction. In some embodiments, the X, Y and Z directions are perpendicular to each other. In some embodiments, the electrically conductive portions 321, 322, 323, 324 have a pitch ranging from about 18 nm to about 30 nm. In some embodiments, the electrically conductive portion 322 is designed to be connected to the middle-of-line contacts 222 shown in FIG. 4.

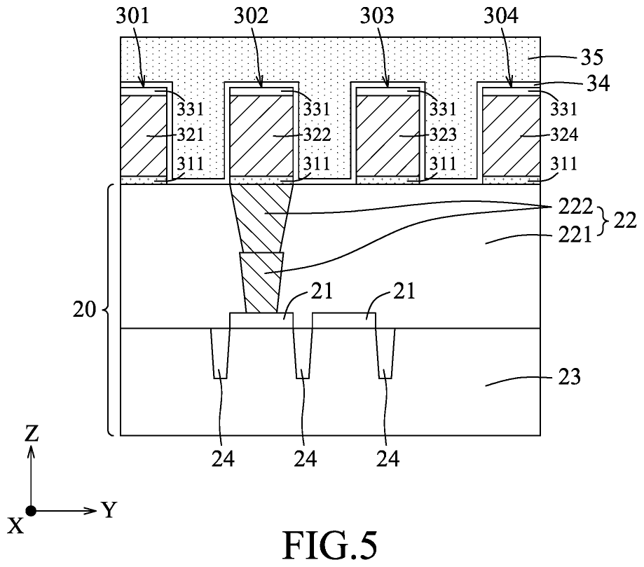

Referring to FIG. 1 and the example illustrated in FIG. 5, the method 100 proceeds to step 103, where a capping layer 34 and a first sacrificial layer 35 are sequentially formed on the structure shown in FIG. 4. FIG. 5 is a schematic sectional view similar to FIG. 4, but illustrating the structure after step 103.

The capping layer 34 is formed along an upper surface of each of the stacking portions 301, 302, 303, 304 and along an inner surface of each of the recesses 305 (see FIG. 4) using a suitable deposition process, such as physical vapor deposition (PVD), thermal chemical vapor deposition (CVD), plasma-enhanced chemical vapor deposition (PECVD), thermal atomic layer deposition (ALD), or plasma-enhanced atomic layer deposition (PEALD). The capping layer 34 is provided for improving adhesion of a subsequently formed element (e.g., the first sacrificial layer 35 or a dielectric portion 50 (see FIG. 17)) to the hard mask portions 331, the electrically conductive portions 321, 322, 323, 324 and/or the dielectric layer 221. In some embodiments, the capping layer 34 is made of a dielectric material such as silicon oxide, silicon nitride, silicon oxycarbide, silicon oxynitride, silicon carbon nitride, silicon oxycarbon nitride, metal oxide (such as aluminum oxide), metal nitride (such as aluminum nitride), metal oxynitride (such as aluminum oxynitride), or combinations thereof. In some embodiments, the capping layer 34 has a thickness ranging from about 2 Å to about 50 Å.

The first sacrificial layer 35 is formed on the capping layer 34 to fill the recesses 305 (see FIG. 4) using a suitable deposition process, such as chemical vapor deposition (CVD) or spin-coating. In some embodiments, the sacrificial layer 35 includes a sacrificial polymer, such as polylactic acid, polycaprolactone, polyurea, poly(methyl methacrylate), poly(ethylene oxide), polyacrylate, polyvinyl alcohol, or combinations thereof. In some embodiments, the first sacrificial layer 31 may be formed by a spin coating process at room temperature followed by a curing process at a temperature ranging from about 100° C. to about 250° C. Other suitable techniques and/or materials for forming the first sacrificial layer 31 are within the contemplated scope of the present disclosure.

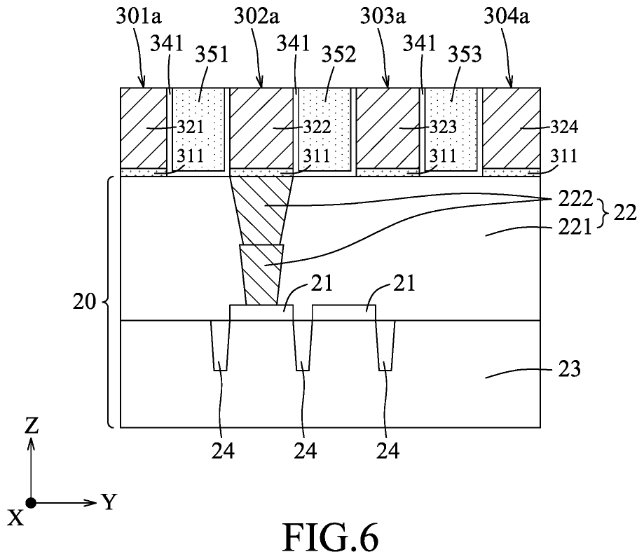

Referring to FIG. 1 and the example illustrated in FIG. 6, the method 100 proceeds to step 104, where a planarization process (for example, but not limited to, chemical mechanical polishing) is performed to expose an upper surface of each of the electrically conductive portions 321, 322, 323, 324. FIG. 6 is a schematic sectional view similar to FIG. 5, but illustrating the structure after step 104.

After step 104, the hard mask portion 331 (see FIG. 5) in each of the stacking portions 301, 302, 303, 304 is removed. The polished stacking portions are respectively denoted by the numerals 301a, 302a, 303a, 304a. The first sacrificial layer 35 (see FIG. 5) is patterned into three sacrificial portions 351, 352, 353. The capping layer 34 (see FIG. 5) is patterned into three capping portions 341, each of which is disposed to separate one of the sacrificial portions 351, 352, 353 from the base structure 20 and two corresponding adjacent ones of the stacking portions 301a, 302a, 303a, 304a.

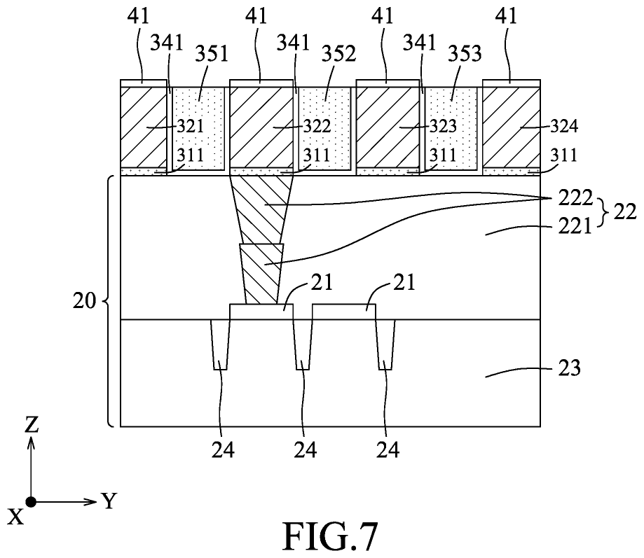

Referring to FIG. 1 and the example illustrated in FIG. 7, the method 100 proceeds to step 105, where masking portions 41 are formed on the electrically conductive portions 321, 322, 323, 324, respectively. FIG. 7 is a schematic sectional view similar to FIG. 6, but illustrating the structure after step 105.

In some embodiments, the masking portions 41 may each be present as a self-assembled monolayer (SAM) which is a layer of self-assembled molecules. The self-assembled molecules can react with a metallic material or a native oxide layer which is naturally formed on the metallic material, and will not react with a dielectric material or a polymeric material, so that the masking portions 41 can be selectively formed on the electrically conductive portions 321, 322, 323, 324, respectively. In some embodiments, the SAM includes a head group which contains phosphorus (P), sulfur(S), or silicon (Si) and a tail group which is connected to the head group and which contains an organic chain, such as hydrocarbon chain (CHₓ) or the like. In some embodiments, the head group of the SAM may include phosphate, sulfate, or silane based materials. In some embodiments, the SAM may include benzotriazole (BTA), phosphonic acid, octadecylphosphonic (ODPA), organosulfur compound, thiol (e.g., dodecanethiol, alkanethiol, or the like), etc. In some embodiments, the SAM may be selectively formed on the electrically conductive portions 321, 322, 323, 324 using a suitable deposition process, such as chemical vapor deposition (CVD), dipping deposition or spin-coating.

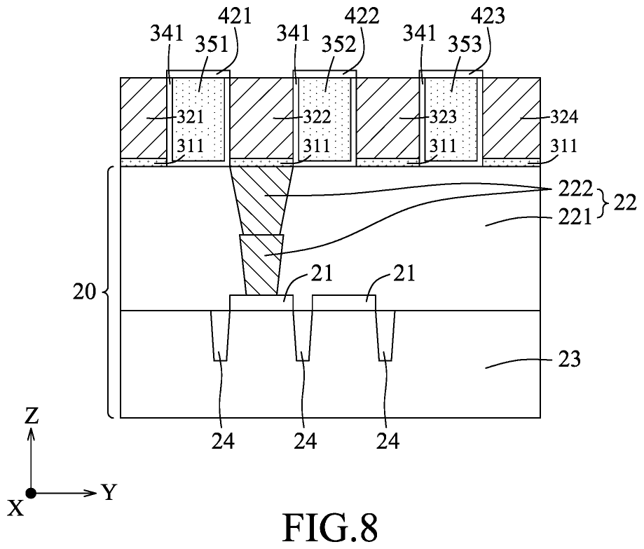

Referring to FIG. 1 and the example illustrated in FIG. 8, the method 100 proceeds to step 106, where blocking portions 421, 422, 423 are selectively formed on the sacrificial portions 351, 352, 353, respectively. In step 106, with the provision of the masking portions 41 (see FIG. 7), the growth of the blocking portions 421, 422, 423 on the electrically conductive portions 321, 322, 323, 324 is inhibited, and the blocking portions 421, 422, 423 are thus selectively formed on the sacrificial portions 351, respectively. As such, the masking portions 41 (see FIG. 7) may each also be referred to as an inhibitor. Afterwards, the masking portions 41 (see FIG. 7) are removed after formation of the blocking portions 421, 422, 423. FIG. 8 is a schematic sectional view similar to FIG. 7, but illustrating the structure after step 106.

Referring back to FIG. 6, each of the capping portions 341 has two end surfaces exposed from a corresponding one of the sacrificial portions 351, 352, 353 after step 104. Referring to FIG. 8, in step 106, each of the blocking portions 421, 422, 423 is further formed on the two end surfaces of a corresponding one of the capping portions 341 which are not covered by the masking portions 41 (see FIG. 7).

In some embodiments, the blocking portions 421, 422, 423 may include metal oxide, metal nitride, or metal carbide. For example, each of the blocking portions 421, 422, 423 may be made of aluminum oxide, aluminum nitride, aluminum carbide, zirconium oxide, zirconium nitride, zirconium carbide, yttrium oxide, yttrium nitride, yttrium carbide, hafnium oxide, hafnium nitride, hafnium carbide, titanium oxide, titanium nitride, titanium carbide, or combinations thereof. It is noted that the material of the blocking portions 421, 422, 423 is different from the material of the capping portions 341 such that the blocking portions 421, 422, 423 may be selectively removed with the capping portions 341 being substantially intact due to different etching selectivities in an etching process. In some embodiments, the blocking portions 421, 422, 423 have a thickness ranging from about 5 Å to about 75 Å. In some embodiments, the blocking portions 421, 422, 423 may be formed by a suitable deposition process, such as thermal atomic layer deposition (ALD), or plasma-enhanced atomic layer deposition (PEALD).

In some embodiments, the masking portions 41 (see FIG. 7) may be removed by a heating, plasma, or wet chemical treatment. In some embodiments, during removal of the masking portions 41 (i.e., the SAM material), the tail group of the SAM material is removed after the heating, plasma, or wet chemical treatment, and the head group of the SAM material may remain on the electrically conductive portions 321, 322, 323, 324 to form a stable phase as a capping layer (not shown) covering the electrically conductive portions 321, 322, 323, 324.

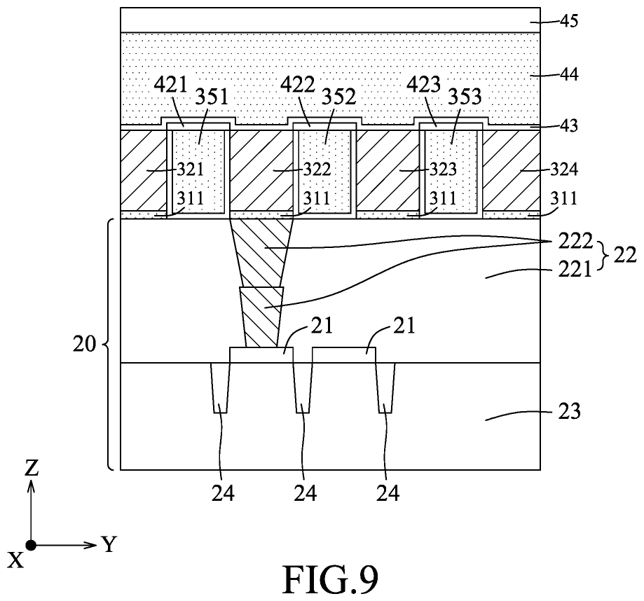

Referring to FIG. 1 and the example illustrated in FIG. 9, the method 100 proceeds to step 107, where an etch stop layer 43, a second sacrificial layer 44 and a hard mask layer 45 are sequentially formed on the structure shown in FIG. 8. FIG. 9 is a schematic sectional view similar to FIG. 8, but illustrating the structure after step 107.

In some embodiments, the etch stop layer 43 is formed to cover the electrically conductive portions 321, 322, 323, 324 and the blocking portions 421, 422, 423 using a suitable deposition process, such as physical vapor deposition (PVD), thermal chemical vapor deposition (CVD), plasma-enhanced chemical vapor deposition (PECVD), thermal atomic layer deposition (ALD), or plasma-enhanced atomic layer deposition (PEALD). The etch stop layer 43 includes silicon oxycarbide, silicon carbon nitride, silicon nitride, silicon oxycarbon nitride, metal oxide (such as aluminum oxide), metal nitride (such as aluminum nitride), metal oxynitride (such as aluminum oxynitride), or combinations thereof. It is noted that the material of the etch stop layer 43 is different from the material of the blocking portions 421, 422, 423 such that the blocking portions 421, 422, 423 may well protect the sacrificial portions 351, 352, 353 when patterning the etch stop layer 43. In some embodiments, the etch stop layer 43 has a thickness ranging from about 2 Å to about 200 Å.

The second sacrificial layer 44 is formed on the etch stop layer 43. Possible materials and techniques suitable for forming the second sacrificial layer 44 are similar to those for the first sacrificial layer 35 as described above with reference to FIG. 5, and thus the details thereof are omitted for the sake of brevity. In some embodiments, the second sacrificial layer 44 may have a thickness ranging from about 100 Å to about 500 Å.

The hard mask layer 45 is formed on the second sacrificial layer 44. Possible materials and techniques suitable for forming the hard mask layer 45 are similar to those for the hard mask layer 33 as described above with reference to FIG. 2, and thus the details thereof are omitted for the sake of brevity.

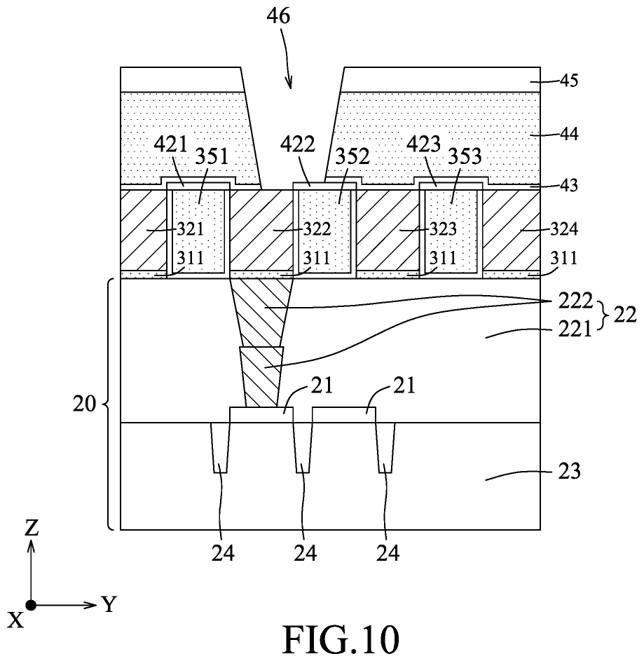

Referring to FIG. 1 and the example illustrated in FIG. 10, the method 100 proceeds to step 108, where a hole 46 is formed to penetrate the hard mask layer 45, the second sacrificial layer 44 and the etch stop layer 43 using a suitable patterning process including lithography and etching processes. FIG. 10 is a schematic sectional view similar to FIG. 9, but illustrating the structure after step 108.

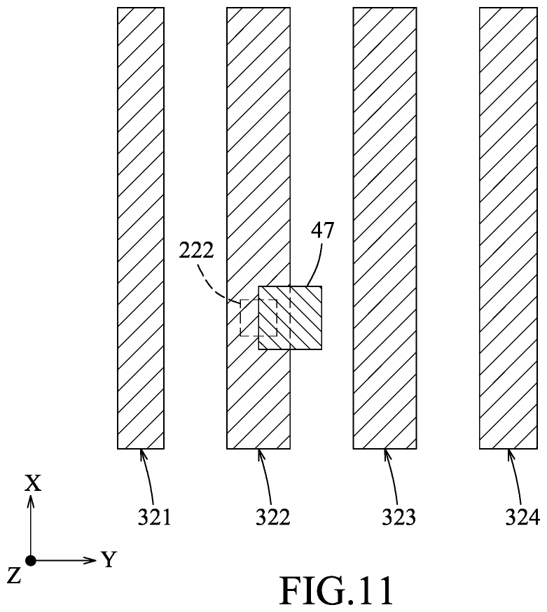

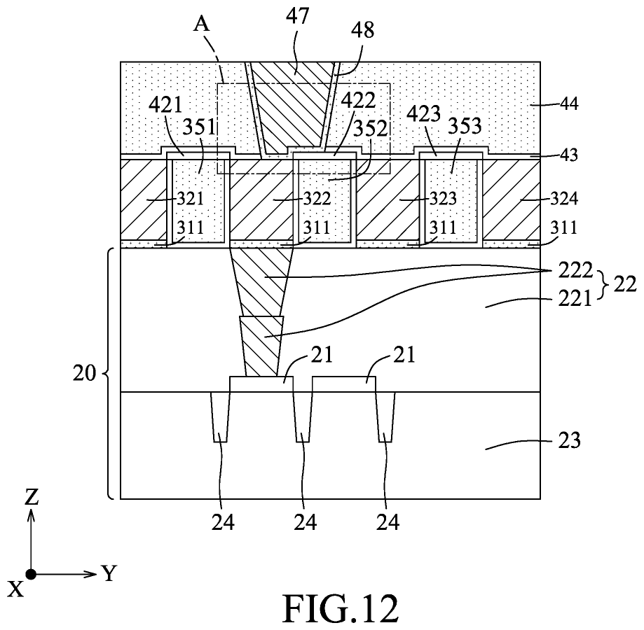

The hole 46 is formed for forming an electrically conductive via 47 (see FIGS. 11 and 12) therein in the following step. In some embodiments, the hole 46 is formed to expose a part of the electrically conductive portion 322. In some embodiments, the blocking portion 422 that is located next to the electrically conductive portion 322 is also partially exposed from the hole 46 (i.e., the electrically conductive via 47 shown in FIGS. 11 and 12 may be landed on both the electrically conductive portion 322 and the blocking portion 422). In some other embodiments not shown herein, according to the size or location of the hole 46, the blocking portion 422 may be not exposed from the hole 46 (i.e., the electrically conductive via may be merely landed on the electrically conductive portion 322).

It is worth noting that, as shown in FIG. 10, since the blocking portion 422 has an etching selectivity different from that of the etch stop layer 43, although the blocking portion 422 is partially exposed from the hole 46, the blocking portion 422 is less likely to be damaged by etchants used in patterning of the etch stop layer 43. The sacrificial portion 352 protected by the blocking portion 422 is also not damaged.

Referring to FIG. 1 and the examples illustrated in FIGS. 11 and 12, the method 100 proceeds to step 109, where an electrically conductive via 47 is formed in the hole 46 (see FIG. 10). FIG. 11 is a schematic plane view similar to FIG. 3, but further illustrating the electrically conductive via 47 formed in step 109. FIG. 12 is a schematic sectional view similar to FIG. 10, but illustrating the structure after step 109.

In some embodiments, formation of the electrically conductive via 47 may include depositing an electrically conductive material layer (not shown) for forming the electrically conductive via 47 to fill the hole 46 (see FIG. 10), followed by a planarization process to expose the second sacrificial layer 44. In some embodiments, possible materials suitable for the electrically conductive material layer are similar to those for the electrically conductive layer 32 as described above with reference to FIG. 2, and thus the details thereof are omitted for the sake of brevity.

In some embodiments, a glue layer (not shown) may be formed before the deposition of the electrically conductive material layer by a suitable deposition process such as physical vapor deposition (PVD), thermal chemical vapor deposition (CVD), or thermal atomic layer deposition (ALD) to improve the adhesion of the electrically conductive material layer to the second sacrificial layer 44, the etch stop layer 43, the electrically conductive portion 322 and the blocking portion 422. After the planarization process, as shown in FIG. 12, the glue layer is formed into a glue portion 48 around the electrically conductive via 47. In some embodiments, the glue portion 48 may also serve as a diffusion barrier to avoid out-diffusion of the metal elements in the electrically conductive via 47. In some embodiments, the glue portion 48 include tantalum (Ta), titanium (Ti), tantalum nitride, titanium nitride, or combinations thereof. The glue portion 48 may be configured as a single layer structure or a multi-layered structure. The material of the glue portion 48 may be the same as or different from the material of the glue portions 311. In some embodiments, the glue portion 48 has a thickness ranging from about 2 Å to about 100 Å.

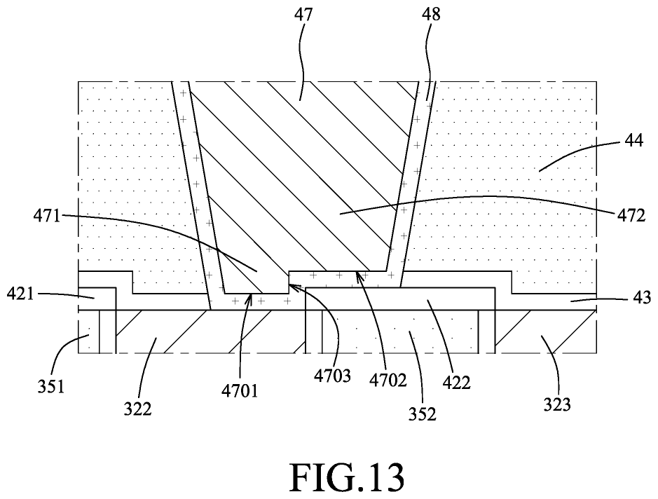

FIG. 13 is a fragmentary enlarged view of area (A) in FIG. 12 in accordance with some embodiments. Before proceeding to the next step, the electrically conductive via 47 includes a first bottom portion 471 which is disposed on the electrically conductive portion 322, and a second bottom portion 472 which is disposed on the blocking portion 422 that is located next to the electrically conductive portion 322. It is noted that the electrically conductive via 47 has a stepwise bottom surface. The step wise bottom surface has a first horizontal region 4701 which is located at an upper surface the electrically conductive portion 322, a second horizontal region 4702 which is located at an upper surface of the blocking portion 422 that is located next to the electrically conductive portion 322, and an interconnecting region 4703 interconnecting the first horizontal region 4701 and the second horizontal region 4702. Furthermore, the second horizontal region 4702 is located at a level higher than a level of the first horizontal region 4701. In other words, referring to FIGS. 12 and 13, a minimum distance between the base structure 20 and the first horizontal region 4701 is smaller than a minimum distance between the base substrate 20 and the second horizontal region 4702.

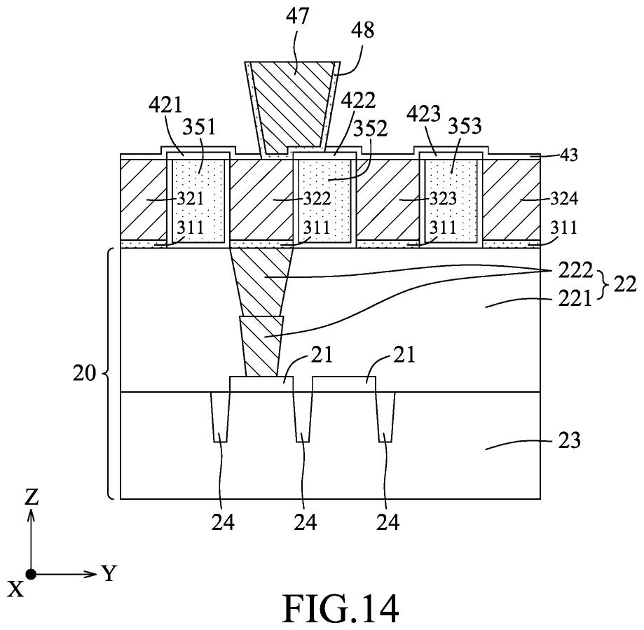

Referring to FIG. 1 and the example illustrated in FIG. 14, the method 100 proceeds to step 110, where the second sacrificial layer 44 (see FIG. 12) is removed by a burn-out operation. In some embodiments, the burn-out operation is performed by exposing the second sacrificial layer 44 to an ultraviolet (UV) light at a temperature ranging from about 385° C. to about 450° C. In some other embodiments, the burn-out operation is performed using a thermal treatment or other suitable treatments. After the burn-out operation, the etch stop layer 43 is exposed. FIG. 14 is a schematic sectional view similar to FIG. 12, but illustrating the structure after step 110.

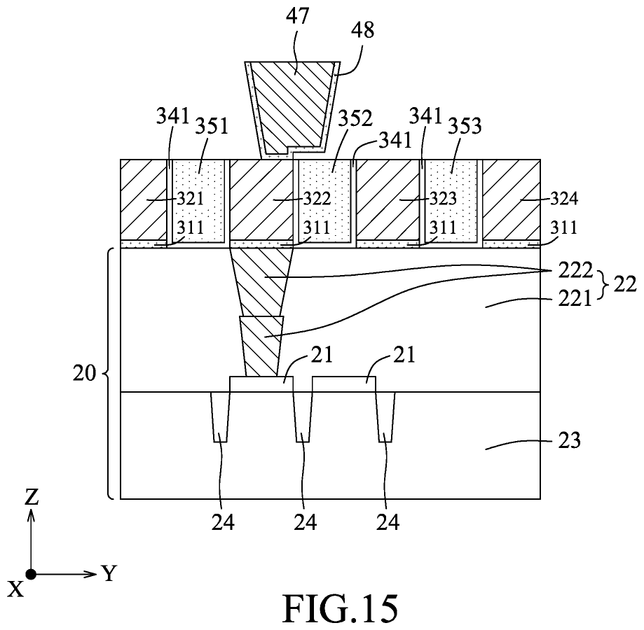

Referring to FIG. 1 and the example illustrated in FIG. 15, the method 100 proceeds to step 111, where the etch stop layer 43 and the blocking portions 421, 422, 423 (see FIG. 14) are removed sequentially. After step 111, the sacrificial portions 351, 352, 353 and the capping portions 341 are exposed. FIG. 15 is a schematic sectional view similar to FIG. 14, but illustrating the structure after step 111.

In some embodiments, the etch stop layer 43 and the blocking portions 421, 422, 423 (see FIG. 14) may be removed by a wet etching process. The wet etching process may utilize multiple solutions each of which contains a wet etchant (i.e., a wet etchant solution). The wet etchant solution has a higher etching selectivity (or higher etching rate) over the elements to be removed so that glue portion 48 and the capping portions 341 can be prevent from being damaged in step 111. In some embodiments, the wet etchant solution may include NH₄OH, H₂SO₄, H₂O₂, HCl, H₂O, HF, HNO₃, diluted HF, O₃, H₃PO₄, or the like, or combinations thereof, but is not limited thereto. The wet etchant solution for removing the etch stop layer 43 may be the same as or different from the wet etchant solution for removing the blocking portions 421, 422, 423. Other chemical solutions suitable for removing the etch stop layer 43 and the blocking portions 421, 422, 423 are within the contemplated scope of the present disclosure.

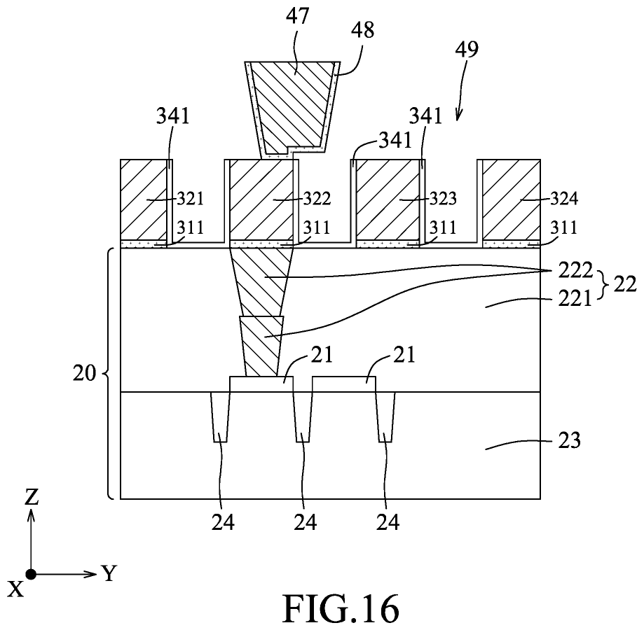

Referring to FIG. 1 and the example illustrated in FIG. 16, the method 100 proceeds to step 112, where the sacrificial portions 351, 352, 353 (see FIG. 15) are removed in a manner similar to that for removing the second sacrificial layer 44 as described above with reference to FIGS. 12 and 14, and thus the details thereof are omitted for the sake of brevity. FIG. 16 is a schematic sectional view similar to FIG. 15, but illustrating the structure after step 112. After step 112, a cavity 49 is thus formed around the electrically conductive portions 321, 322, 323, 324 and the electrically conductive via 47.

Referring to FIG. 1 and the example illustrated in FIG. 17, the method 100 proceeds to step 113, where a dielectric portion 50 is formed in the cavity 49 (see FIG. 16), thereby obtaining the semiconductor structure 80 including the interconnect structure 60 formed on the base structure 20. FIG. 17 is a schematic sectional view similar to FIG. 16, but illustrating the structure after step 113.

In some embodiments, possible materials suitable for the dielectric portion 50 are similar to those for the dielectric layer 221 as described above with reference to FIG. 2, and thus the details thereof are omitted for the sake of brevity. In some embodiments, the dielectric portion 50 is formed by filling the cavity 49 with a dielectric material for forming the dielectric portion 50 to cover the electrically conductive via 47 using a suitable deposition process such as flowable chemical vapor deposition (CVD) or spin-coating, followed by a planarization process to remove an excess of the dielectric material and to expose the electrically conductive via 47.

After step 113, the electrically conductive portions 321, 322, 323, 324 are formed in a lower part 51 of the dielectric portion 50, and the electrically conductive via 47 is formed in an upper part 52 of the dielectric portion 50. Since the lower part 51 and the upper part 52 are sequentially formed by a bottom-up deposition process, the lower part 51 and the upper part 52 are made of the same material, and are in direct contact with each other. Referring to FIGS. 12 and 17, the electrically conductive via 47 is substantially not changed.

In some embodiments, the electrically conductive portions 321, 322, 323, 324 serve as metal lines in the first metal layer (MO) with the smallest pitch in the BEOL portion and are formed in the lower part 51, and the electrically conductive via 47 serves as a metal via in the first via layer (VO) and is formed in the upper part 52. Since the lower part 51 formed among the electrically conductive portions 321, 322, 323, 324 is formed together with the upper part 52 in the same step, the lower part 51 can be effectively prevented from being damaged during formation of the upper part 52, and can be kept at a relatively lower dielectric capacitance.

In some embodiments, the semiconductor structure 80 may further include additional features, and/or some features present in the semiconductor structure 80 may be modified, replaced, or eliminated without departure from the spirit and scope of the present disclosure. In some embodiments, the interconnect structure 60 may further include additional features, and/or some features present in the interconnect structure 60 may be modified, replaced, or eliminated without departure from the spirit and scope of the present disclosure. In some embodiments, some steps in the method 100 may be modified, replaced, or eliminated without departure from the spirit and scope of the present disclosure.

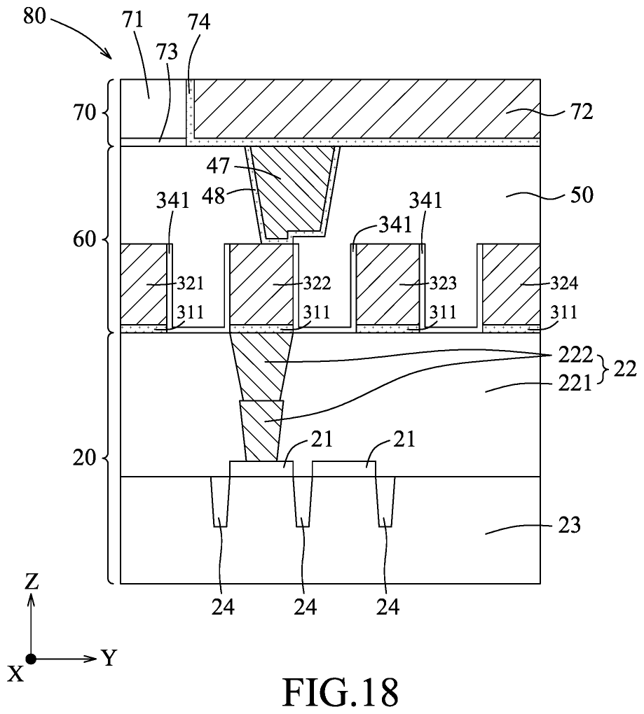

For example, in some embodiments, the semiconductor structure 80 may further include multiple interconnect layers 70 (one of which is shown in FIG. 18) formed on the interconnect structure 60 by a dual damascene process, a single damascene process, or other suitable back-end-of-line (BEOL) techniques. Each of the interconnect layers 70 may include an inter-metal dielectric (IMD) feature 71 and multiple electrically conductive elements 72 (for example, metal lines and/or metal vias, one of the metal lines 72 is shown in FIG. 18) formed in the IMD feature 71. In some embodiments, for example, the interconnect layer 70 shown in FIG. 18 may be formed by (i) forming an etch stop layer 73 and the IMD feature 71 on the interconnect structure 60 in such order by suitable deposition processes, (ii) patterning the IMD feature 71 and the etch stop layer 73 by a lithography process and an etching process to form a trench (not shown), (iii) sequentially forming a glue layer for forming an glue portion 74 and an electrically conductive material layer for forming the metal line 72 to fill the trench by suitable deposition processes, and (iv) performing a planarization process to exposed the IMD feature 71 such that the glue layer is formed into the glue portion 74 and such that the electrically conductive material layer is formed into the metal line 72.

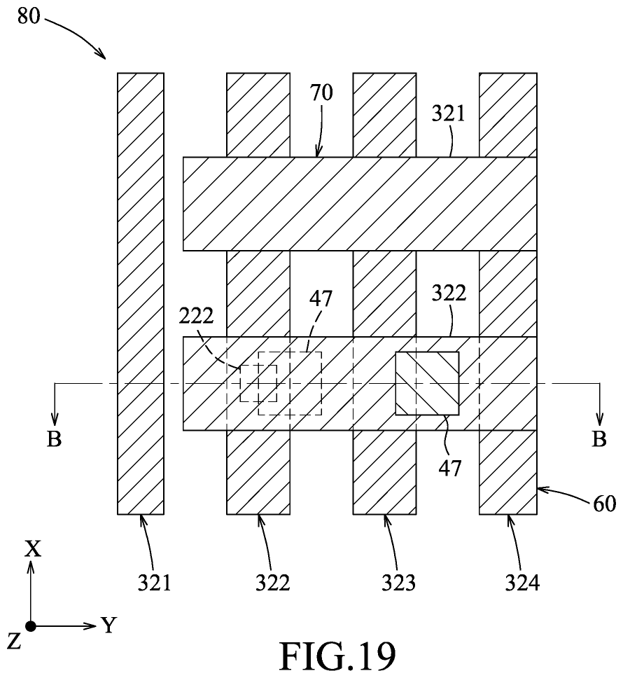

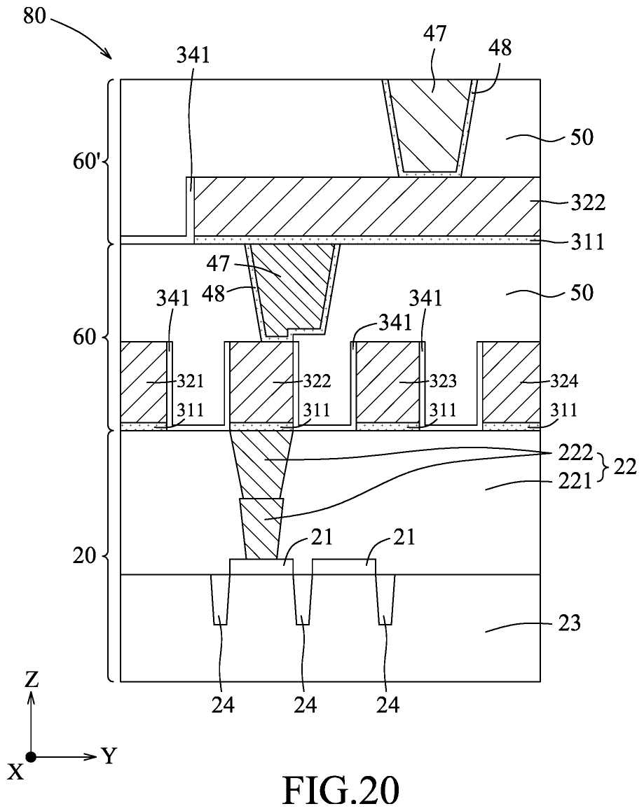

In some other embodiments, as shown in FIGS. 19 and 20, the semiconductor structure 80 may further include another interconnect structure 60′ which has a structure similar to the interconnect structure 60, except that the electrically conductive portions 321, 322 of the interconnect structure 60′ are each elongated in the Y direction and spaced apart from each other in the X direction (one of the electrically conductive portions 322 in the interconnect structure 60′ is shown in FIG. 20, and two of the electrically conductive portions 321, 322 in the interconnect structure 60′ are shown in FIG. 19). FIG. 19 is a schematic plane view similar to FIG. 11, but further illustrating the electrically conductive portions 321, 322 and the electrically conductive via 47 in the interconnect structure 60′. The interconnect structure 60′ may be formed on the interconnect structure 60 in a manner similar to the manner as described above with reference to FIGS. 2 to 17, and thus the details thereof are omitted for the sake of brevity.

In summary, the interconnect structure of the disclosure includes metal portions having a low electrical resistance, and a dielectric portion having an effective low-k value and formed around the metal portions, and such interconnect structure is beneficial for achieving a relatively low resistive-capacitive (RC) delay because the dielectric portion in the interconnect structure of this disclosure is formed after the metal portions, thereby minimizing the damage to the dielectric portion. To be specific, the metal portions may include metal lines of a lower metal layer and metal via(s) of an upper via layer. Although an etch stop layer is still used for controlling the etching process during formation of the metal via(s), the dielectric portion is refilled after formation of the metal portions and after removal of the etch stop layer and other sacrificial portions. As such, in the step for forming the dielectric portion, a lower part of the dielectric portion among the metal lines, which is formed intermediately before formation of an upper part of the dielectric portion among the metal via(s), will be not damaged. In addition, the upper part of the dielectric portion is also less likely to be damaged because the upper part of the dielectric portion is formed after formation the metal via(s). Furthermore, the absence of the etch stop layer in the interconnect structure is also beneficial for lowering the RC delay of the interconnect structure. Therefore, the interconnect structure of the disclosure can be applied in the next generation BEOL interconnect scheme.

In accordance with some embodiments of the present disclosure, a method for manufacturing an interconnect structure includes: forming sacrificial portions and electrically conductive portions on a base structure such that the sacrificial portions are disposed to alternate with the electrically conductive portions in a first direction, and such that each of the sacrificial portions and the electrically conductive portions is elongated in a second direction transverse to the first direction; forming blocking portions respectively on the sacrificial portions; forming a sacrificial layer to cover the electrically conductive portions and the blocking portions; forming an electrically conductive via which extends through the sacrificial layer so as to permit the electrically conductive via to be electrically connected to one of the electrically conductive portions; after formation of the electrically conductive via, performing a removal process to remove the sacrificial layer, the blocking portions and the sacrificial portions so as to form a cavity; and forming a dielectric portion to fill the cavity.

In accordance with some embodiments of the present disclosure, the sacrificial portions include polyurea, polylactic acid, polycaprolactone, poly(ethylene oxide), polyacrylate, polyvinyl alcohol, poly(methyl methacrylate), or combinations thereof, and the sacrificial layer includes polyurea, polylactic acid, polycaprolactone, poly(ethylene oxide), polyacrylate, polyvinyl alcohol, poly(methyl methacrylate), or combinations thereof.

In accordance with some embodiments of the present disclosure, the blocking portions include metal oxide, metal nitride, metal oxynitride, or combinations thereof.

In accordance with some embodiments of the present disclosure, before performing the removal process, the electrically conductive via includes a first bottom portion which is disposed on the one of the electrically conductive portions, and a second bottom portion which is disposed on one of the blocking portions that is located next to the one of the electrically conductive portions.

In accordance with some embodiments of the present disclosure, before performing the removal process, a bottom surface of the electrically conductive via has a first horizontal region which is located at an upper surface of the one of the electrically conductive portions, a second horizontal region which is located at an upper surface of one of the blocking portions that is located next to the one of the electrically conductive portions, and an interconnecting region interconnecting the first horizontal region and the second horizontal region.

In accordance with some embodiments of the present disclosure, the second horizontal region is located at a level higher than a level of the first horizontal region.

In accordance with some embodiments of the present disclosure, the method further includes forming capping portions, each of which is disposed to separate one of the sacrificial portions from the base structure and two corresponding adjacent ones of the electrically conductive portions.

In accordance with some embodiments of the present disclosure, the capping portions include silicon oxide, silicon nitride, silicon oxycarbide, silicon oxynitride, silicon carbon nitride, silicon oxycarbon nitride, metal oxide, metal nitride, metal oxynitride, or combinations thereof, and the capping portions are made of a material different from a material of the blocking portions.

In accordance with some embodiments of the present disclosure, before forming the blocking portions, each of the capping portions has two end surfaces exposed from a corresponding one of the sacrificial portions, and each of the blocking portions is further formed on the two end surfaces of a corresponding one of the capping portions.

In accordance with some embodiments of the present disclosure, formation of the capping portions, the sacrificial portions and the electrically conductive portions includes: forming an electrically conductive layer on the base structure; patterning the electrically conductive layer to form the electrically conductive portions and recesses, each of the recesses being formed between two adjacent ones of the electrically conductive portions; forming a capping layer along an upper surface of each of the electrically conductive portions and along an inner surface of each of the recesses; forming a preformed layer on the capping layer to fill the recesses; and performing a planarization process to expose the upper surface of each of the electrically conductive portions, such that the capping layer is formed into the capping portions, and such that the preformed layer is formed into the sacrificial portions.

In accordance with some embodiments of the present disclosure, formation of the blocking portions includes: forming masking portions respectively on the electrically conductive portions; forming the blocking portions respectively on the sacrificial portions; and removing the masking portions after forming the blocking portions.

In accordance with some embodiments of the present disclosure, the method further includes forming glue portions, each of which is disposed between the base structure and a corresponding one of the electrically conductive portions.

In accordance with some embodiments of the present disclosure, the glue portions includes titanium, tantalum, titanium nitride, tantalum nitride, or combinations thereof.

In accordance with some embodiments of the present disclosure, a method for manufacturing an interconnect structure includes: forming first sacrificial portions and electrically conductive portions on a base structure such that the sacrificial portions are disposed to alternate with the electrically conductive portions in a first direction, and such that each of the sacrificial portions and the electrically conductive portions is elongated in a second direction transverse to the first direction; forming a sacrificial layer to cover the sacrificial portions and the electrically conductive portions; forming an electrically conductive via which extends through the sacrificial layer so as to permit the electrically conductive via to be electrically connected to one of the electrically conductive portions; after formation of the electrically conductive via, performing a removal process to remove the sacrificial layer and the sacrificial portions so as to form a cavity; and forming a dielectric portion to fill the cavity.

In accordance with some embodiments of the present disclosure, the method further includes: forming an etch stop layer to cover the electrically conductive portions and the sacrificial portions before forming the sacrificial layer. The sacrificial layer is formed on the etch stop layer. The electrically conductive via is formed to further extend through the etching stop layer so as to permit the electrically conductive via to be electrically connected to the one of the electrically conductive portions. The etching stop layer is removed during the removal process.

In accordance with some embodiments of the present disclosure, the etch stop layer includes silicon oxycarbide, silicon nitride, silicon carbon nitride, silicon oxycarbon nitride, metal oxide, metal nitride, metal oxynitride, or combinations thereof.

In accordance with some embodiments of the present disclosure, formation of the electrically conductive via includes patterning the sacrificial layer and the etch stop layer to form a hole, and forming the electrically conductive via in the hole.

In accordance with some embodiments of the present disclosure, an interconnect structure includes: a dielectric portion disposed on a base structure; a first electrically conductive portion and a second electrically conductive portion which are disposed in a lower part of the dielectric portion, and which are spaced apart from each other; and an electrically conductive via disposed in an upper part of the dielectric portion such that the electrically conductive via is capable of being electrically connected to the first electrically conductive portion, the electrically conductive via having a stepwise bottom surface, the stepwise bottom surface having a first horizontal region that is located at the first electrically conductive portion. The lower part and the upper part of the dielectric portion are made of a same material.

In accordance with some embodiments of the present disclosure, the lower part is in direct contact with the upper part.

In accordance with some embodiments of the present disclosure, the stepwise bottom surface of the electrically conductive via further has a second horizontal region which is spaced apart from the first electrically conductive portion, and an interconnecting region interconnecting the first horizontal region and the second horizontal region. The second horizontal region is being located at a level higher than a level of the first horizontal region.

In accordance with some embodiments of the present disclosure, a method for manufacturing an interconnect structure includes: forming a first electrically conductive portion and a second electrically conductive portion such that the first electrically conductive portion and the second electrically conductive portion are spaced apart from each other; forming an electrically conductive via so as to permit the electrically conductive via to be electrically connected to the first electrically conductive portion, the electrically conductive via having a stepwise bottom surface, a first horizontal region of the stepwise bottom surface being located at the first electrically conductive portion; and forming a dielectric portion after forming the first electrically conductive portion and the second electrically conductive portion and after forming the electrically conductive via such that the first electrically conductive portion and the second electrically conductive portion are disposed in a lower part of the dielectric portion, and such that the electrically conductive via is disposed in an upper part of the dielectric portion.

In accordance with some embodiments of the present disclosure, the lower part and the upper part of the dielectric portion are made of a same material.

In accordance with some embodiments of the present disclosure, the stepwise bottom surface of the electrically conductive via further has a second horizontal region which is spaced apart from the first electrically conductive portion, and an interconnecting region interconnecting the first horizontal region and the second horizontal region. The second horizontal region is located at a level higher than a level of the first horizontal region.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming sacrificial portions and electrically conductive portions on a base structure such that the sacrificial portions are disposed to alternate with the electrically conductive portions in a first direction, and such that each of the sacrificial portions and the electrically conductive portions is elongated in a second direction transverse to the first direction;
forming blocking portions respectively on the sacrificial portions;
forming a sacrificial layer to cover the electrically conductive portions and the blocking portions;
forming an electrically conductive via which extends through the sacrificial layer so as to permit the electrically conductive via to be electrically connected to one of the electrically conductive portions;
after formation of the electrically conductive via, performing a removal process to remove the sacrificial layer, the blocking portions and the sacrificial portions so as to form a cavity; and
forming a dielectric portion to fill the cavity.

2. The method as claimed in claim 1, wherein
the sacrificial portions include polyurea, polylactic acid, polycaprolactone, poly(ethylene oxide), polyacrylate, polyvinyl alcohol, poly(methyl methacrylate), or combinations thereof, and
the sacrificial layer includes polyurea, polylactic acid, polycaprolactone, poly(ethylene oxide), polyacrylate, polyvinyl alcohol, poly(methyl methacrylate), or combinations thereof.

3. The method as claimed in claim 1, wherein the blocking portions include metal oxide, metal nitride, metal oxynitride, or combinations thereof.

4. The method as claimed in claim 1, wherein before performing the removal process, the electrically conductive via includes a first bottom portion which is disposed on the one of the electrically conductive portions, and a second bottom portion which is disposed on one of the blocking portions that is located next to the one of the electrically conductive portions.

5. The method as claimed in claim 1, wherein before performing the removal process, a bottom surface of the electrically conductive via has
a first horizontal region which is located at an upper surface of the one of the electrically conductive portions,
a second horizontal region which is located at an upper surface of one of the blocking portions that is located next to the one of the electrically conductive portions, and
an interconnecting region interconnecting the first horizontal region and the second horizontal region.

6. The method as claimed in claim 5, wherein the second horizontal region is located at a level higher than a level of the first horizontal region.

7. The method as claimed in claim 1, further comprising forming capping portions, each of which is disposed to separate one of the sacrificial portions from the base structure and two corresponding adjacent ones of the electrically conductive portions.

8. The method as claimed in claim 7, wherein the capping portions include silicon oxide, silicon nitride, silicon oxycarbide, silicon oxynitride, silicon carbon nitride, silicon oxycarbon nitride, metal oxide, metal nitride, metal oxynitride, or combinations thereof, the capping portions being made of a material different from a material of the blocking portions.

9. The method as claimed in claim 7, wherein
before forming the blocking portions, each of the capping portions has two end surfaces exposed from a corresponding one of the sacrificial portions, and
each of the blocking portions is further formed on the two end surfaces of a corresponding one of the capping portions.

10. The method as claimed in claim 7, wherein formation of the capping portions, the sacrificial portions and the electrically conductive portions includes
forming an electrically conductive layer on the base structure,
patterning the electrically conductive layer to form the electrically conductive portions and recesses, each of the recesses being formed between two adjacent ones of the electrically conductive portions,
forming a capping layer along an upper surface of each of the electrically conductive portions and along an inner surface of each of the recesses,
forming a preformed layer on the capping layer to fill the recesses, and
performing a planarization process to expose the upper surface of each of the electrically conductive portions, such that the capping layer is formed into the capping portions, and such that the preformed layer is formed into the sacrificial portions.

11. The method as claimed in claim 1, wherein formation of the blocking portions includes
forming masking portions respectively on the electrically conductive portions,
forming the blocking portions respectively on the sacrificial portions, and
removing the masking portions after forming the blocking portions.

12. The method as claimed in claim 1, further comprising forming glue portions, each of which is disposed between the base structure and a corresponding one of the electrically conductive portions.

13. The method as claimed in claim 12, wherein the glue portions includes titanium, tantalum, titanium nitride, tantalum nitride, or combinations thereof.

14. A method for manufacturing an interconnect structure, comprising:
forming first sacrificial portions and electrically conductive portions on a base structure such that the sacrificial portions are disposed to alternate with the electrically conductive portions in a first direction, and such that each of the sacrificial portions and the electrically conductive portions is elongated in a second direction transverse to the first direction;
forming a sacrificial layer to cover the sacrificial portions and the electrically conductive portions;
forming an electrically conductive via which extends through the sacrificial layer so as to permit the electrically conductive via to be electrically connected to one of the electrically conductive portions;
after formation of the electrically conductive via, performing a removal process to remove the sacrificial layer and the sacrificial portions so as to form a cavity; and
forming a dielectric portion to fill the cavity.

15. The method as claimed in claim 14, further comprising forming an etch stop layer to cover the electrically conductive portions and the sacrificial portions before forming the sacrificial layer,
the sacrificial layer being formed on the etch stop layer,
the electrically conductive via being formed to further extend through the etching stop layer so as to permit the electrically conductive via to be electrically connected to the one of the electrically conductive portions,
the etching stop layer being removed during the removal process.

16. The method as claimed in claim 15, wherein the etch stop layer includes silicon oxycarbide, silicon nitride, silicon carbon nitride, silicon oxycarbon nitride, metal oxide, metal nitride, metal oxynitride, or combinations thereof.

17. The method as claimed in claim 15, wherein formation of the electrically conductive via includes
patterning the sacrificial layer and the etch stop layer to form a hole, and
forming the electrically conductive via in the hole.

18. An interconnect structure, comprising:
a dielectric portion disposed on a base structure;
a first electrically conductive portion and a second electrically conductive portion which are disposed in a lower part of the dielectric portion, and which are spaced apart from each other; and
an electrically conductive via disposed in an upper part of the dielectric portion such that the electrically conductive via is capable of being electrically connected to the first electrically conductive portion, the electrically conductive via having a stepwise bottom surface, the stepwise bottom surface having a first horizontal region that is located at the first electrically conductive portion,
the lower part and the upper part of the dielectric portion being made of a same material.

19. The interconnect structure as claimed in claim 18, wherein the lower part is in direct contact with the upper part.

20. The interconnect structure as claimed in claim 18, wherein the stepwise bottom surface of the electrically conductive via further has a second horizontal region which is spaced apart from the first electrically conductive portion and an interconnecting region interconnecting the first horizontal region and the second horizontal region, the second horizontal region being located at a level higher than a level of the first horizontal region.
